(19) United States
(12) Patent Application Publication
(10) Pub. No.: US 2023/0387824 A1
(43) Pub. Date: Nov. 30, 2023

(54) RAILWAY-VEHICLE POWER CONVERSION APPARATUS

(71) Applicants: KABUSHIKI KAISHA TOSHIBA, Tokyo (JP); Toshiba Infrastructure Systems & Solutions Corporation, Kawasaki-shi (JP)

(72) Inventor: Hiroomi SUZUKI, Koshigaya (JP)

(73) Assignees: KABUSHIKI KAISHA TOSHIBA, Tokyo (JP); Toshiba Infrastructure Systems & Solutions Corporation, Kawasaki-shi (JP)

(21) Appl. No.: 18/449,883

(22) Filed: Aug. 15, 2023

Related U.S. Application Data
(63) Continuation of application No. PCT/JP2022/003212, filed on Jan. 28, 2022.

(30) Foreign Application Priority Data
Feb. 16, 2021 (JP) 2021-022363

(51) Int. Cl. H02M 7/00; B61C 17/00

(52) U.S. Cl. CPC H02M 7/003; B61C 17/00; H05K 7/2089

(57) ABSTRACT

According to an embodiment, a railway-vehicle power conversion apparatus includes: a switching element; a capacitor connected to the switching element; and a gate substrate that supplies a drive signal to the switching element, in which the capacitor is held by a capacitor holding frame, and the gate substrate is attached and secured to the capacitor.

### CROSS-REFERENCE TO RELATED APPLICATION

This application is a Continuation Application of PCT Application No. PCT/JP2022/003212, filed Jan. 28, 2022 and based upon and claiming the benefit of priority from Japanese Patent Application No. 2021-022363, filed Feb. 16, 2021, the entire contents of all of which are incorporated herein by reference.

### FIELD

Embodiments described herein relate generally to a railway-vehicle power conversion apparatus.

### BACKGROUND

In a railway-vehicle power conversion apparatus, a power unit equipped with a switching element includes a cooler, a conductor, a capacitor, and a gate substrate, in addition to the switching element.

The switching element is disposed on the cooler and is cooled with its bottom face in contact with the cooler.

The switching element has an upper face provided with a main terminal and a gate terminal to which the capacitor that suppresses ripple current due to switching and the gate substrate that supplies a gate signal to the switching element are connected.

In recent years, downsized vehicular power conversion apparatuses have been required. Adoption of a wide-bandgap semiconductor achieves downsized switching elements with resistance to voltage. In addition, such downsized switching elements contribute to downsizing of coolers because of the heat-generation faces thereof.

Meanwhile, regarding structural members, such as sheet metal, no large change has been made. Thus, for example, reduction of structural members enables reductions in size and weight.

### BRIEF DESCRIPTION OF THE DRAWINGS

FIG. 1 illustrates the configuration of a railway-vehicle power conversion apparatus according to a first embodiment.

FIG. 2 is a sectional view of the railway-vehicle power conversion apparatus according to the first embodiment.

FIG. 3 is a top view of the railway-vehicle power conversion apparatus according to the first embodiment.

### DETAILED DESCRIPTION

According to one embodiment, a railway-vehicle power conversion apparatus includes: a switching element; a capacitor connected to the switching element; and a gate substrate that supplies a drive signal to the switching element, in which the capacitor is held by a capacitor holding frame, and the gate substrate is attached to the capacitor.

Embodiments is to provide a vehicular power conversion apparatus small in size and light in weight, in which a gate substrate is attached to a capacitor with less constituent sheet metal.

Embodiments will be described below with reference to the drawings.

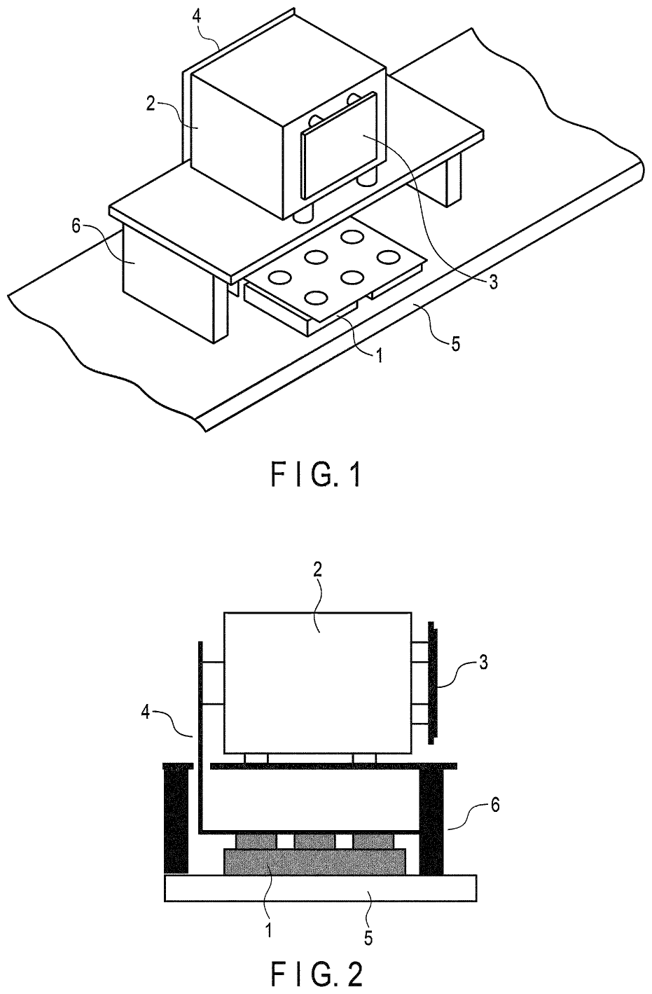

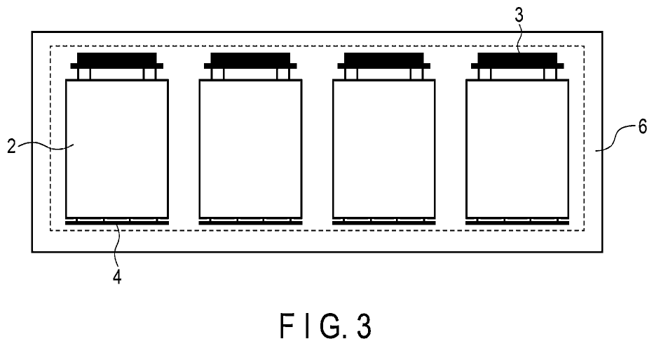

FIG. 1 illustrates the configuration of a railway-vehicle power conversion apparatus according to a first embodiment. FIG. 2 is a sectional view of the railway-vehicle power conversion apparatus according to the first embodiment. FIG. 3 is a top view of the railway-vehicle power conversion apparatus according to the first embodiment. Note that, referring to FIG. 3, such a plurality of railway-vehicle power conversion apparatuses as illustrated in FIG. 1 is provided side by side.

A railway-vehicle power conversion apparatus includes a switching module 1, a capacitor 2, a conductor 3, a gate substrate 4, a cooler 5, and a capacitor holding frame 6.

The switching module 1 serves as an inverter that converts input direct-current power into alternating-current power or a converter that converts input alternating-current power into direct-current power, in the power conversion apparatus. The switching module 1 may include a switching element and a diode in antiparallel connection with the switching element or may include a switching element and a diode for a one-phase part in the power conversion apparatus.

The capacitor 2 is connected to the switching module 1 through the conductor 3 and suppresses ripple current due to switching of the switching module 1.

The gate substrate 4 is connected to a drive terminal of the switching module 1 through a signal line (not illustrated) and supplies a gate signal to the switching module 1.

The switching module 1 is disposed with its bottom face in contact with the cooler 5. The cooler 5 cools the switching module 1.

The capacitor holding frame 6 is provided on the cooler 5 and holds the capacitor 2. Note that, herein, the capacitor holding frame 6 is provided covering the switching module 1, and the capacitor 2 is provided above the switching module 1.

The capacitor 2 has a face to which the gate substrate 4 is attached. Note that, referring to FIG. 1, the gate substrate 4 is attached to the face opposite to the face to which the conductor 3 is attached. However, the gate substrate 4 may be attached to any face of the capacitor 2.

Attachment of a gate substrate 4 in a typical power conversion apparatus will be now described. In typical power conversion apparatuses, as a frame (sheet metal) for attachment of a gate substrate 4, a dedicated frame is often provided for a gate substrate 4.

Conceivable reasons are as follows: separate handling because, in general, the switching module 1 or the capacitor 2 is high in voltage, whereas the gate substrate 4 is relatively low in voltage; easy individual replacement in a case where trouble occurs in the switching module 1 or trouble occurs in the gate substrate 4; and reduction of the influence of noise with the switching module 1 and the gate substrate 4 disposed at close range. From a viewpoint of reductions in weight and size, a dedicated frame for holding the gate substrate 4 is required, leading to an increase in the number of structural members.

In contrast to this, in the present embodiment, since the gate substrate 4 is attached to a face of the capacitor 2, no dedicated frame for attachment of the gate substrate 4 is required, enabling achievement of a power conversion apparatus light in weight and small in size.

The capacitor 2 does not act as a source that generates, for example, harmonic noise, and thus has no influence of hindrance on the function of the attached gate substrate 4.

As illustrated in FIG. 3, a unit including a switching module 1, a capacitor 2, and a gate substrate 4 is provided, for example, as a single power conversion apparatus or as a one-phase part in a single power conversion apparatus. Thus, replacement can be easily carried out per unit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A railway-vehicle power conversion apparatus comprising:
a switching element;
a capacitor connected to the switching element; and
a gate substrate that supplies a drive signal to the switching element, wherein
the capacitor is held by a capacitor holding frame, and
the gate substrate is attached to the capacitor.

2. The railway-vehicle power conversion apparatus according to claim 1, wherein
the switching element is attached to a cooler, and
the capacitor holding frame is attached to the cooler.

3. The railway-vehicle power conversion apparatus according to claim 2, wherein a plurality of units is provided on the cooler, each of the units including the switching element, the capacitor, the gate substrate, and the capacitor holding frame.
